(19) United States
(12) Patent Application Publication
(10) Pub. No.: US 2022/0012404 A1
(43) Pub. Date: Jan. 13, 2022

(54) IMAGE MATCHING METHOD AND ARITHMETIC SYSTEM FOR PERFORMING IMAGE MATCHING PROCESS

(71) Applicant: TASMIT, INC., Yokohama (JP)

(72) Inventor: Taihei MORI, Yokohama (JP)

(21) Appl. No.: 17/311,997

(22) PCT Filed: Nov. 18, 2019
(86) PCT No.: PCT/JP2019/045087

§ 371 Date: Jun. 8, 2021

(30) Foreign Application Priority Data
Dec. 11, 2018 (JP) 2018-231749

(51) Int. Cl. G06F 30/398; G06T 7/00; G06F 30/27

(52) U.S. Cl. CPC G06F 30/398; G06F 30/27; G06T 7/001

(57) ABSTRACT

The present invention relates to an image matching process for aligning a pattern on design data with a pattern on an image, and particularly to an image matching process using a model constructed by machine learning. The method includes: converting a designated CAD pattern on design data into a CAD image (301); inputting the CAD image (301) into a model constructed by machine learning; outputting a pseudo image (321) from the model by performing calculations according to an algorithm defined by the model; and determining a pattern having a shape closest to a shape of a CAD pattern (322) on the pseudo image (321). The determined pattern is one of patterns on an image generated by an image generating device (100).

### TECHNICAL FIELD

The present invention relates to an image matching process for aligning a pattern on design data with a pattern on an image, and particularly to an image matching process using a model constructed by machine learning.

### BACKGROUND ART

There is a known pattern inspection method for semiconductor devices using die to database technique (for example, see patent document 1). A typical pattern inspection method includes generating an image of a pattern on a wafer with a scanning electron microscope, and comparing the pattern on the image with a CAD pattern on design data (also called CAD data) to detect a defect of the pattern on the wafer. As a preprocess of such a pattern inspection method, a matching process is performed to align the CAD pattern on the design data with the pattern on the image.

FIG. 13 is a schematic diagram showing an example of the matching process. The matching process executes an algorithm of comparing a CAD pattern 501 on design data with each one of a large number of patterns 505-1 to 505-N located within a certain area on an image, and determining a pattern 505-n which is closest to the shape of the CAD pattern 501.

### CITATION LIST

### Patent Literature

Patent document 1: Japanese laid-open patent publication No. 2011-17705

### SUMMARY OF INVENTION

### Technical Problem

However, the above-described matching process entails a long processing time because the CAD pattern 501 should be compared with a large number of patterns 505-1 to 505-N on the image. Furthermore, the pattern 505-n on the image corresponding to the CAD pattern 501 is deformed when the pattern is formed on the wafer and/or the image of the pattern on the wafer is generated. Therefore, as shown in FIG. 14, there may be a large difference in shape between the CAD pattern 501 and the pattern 505-n. As a result, the matching process may fail.

Therefore, the present invention provides a method and an apparatus capable of correctly performing a matching process between a CAD pattern on design data and a corresponding pattern on an image.

### Solution to Problem

In one aspect, there is provided a method comprising: converting a designated CAD pattern on design data into a CAD image; inputting the CAD image into a model constructed by machine learning; outputting a pseudo image from the model by performing calculations according to an algorithm defined by the model; and determining a pattern having a shape closest to a shape of a CAD pattern on the pseudo image, the determined pattern being one of patterns on an image generated by an image generating device.

In one aspect, the model comprises a model constructed by the machine learning using training data containing at least multiple CAD images converted from multiple CAD patterns on the design data and multiple images generated by the image generating device, the multiple images corresponding to the multiple CAD images.

In one aspect, the training data further contains training additional information data, and the training additional information data contains at least one of position information of the multiple CAD patterns, peripheral images converted from other CAD patterns existing around the multiple CAD patterns, and layer images converted from other CAD patterns existing above or below the CAD patterns.

In one aspect, inputting the CAD image into the model comprises inputting the CAD image and additional information data into the model, and the additional information data contains at least one of position information of the designated CAD pattern, a peripheral image converted from a CAD pattern existing around the designated CAD pattern, and a layer image converted from a CAD pattern existing above or below the designated CAD pattern.

In one aspect, the method further comprises performing machine learning to adjust parameters of the model such that a CAD pattern on a pseudo image output from the model matches a corresponding pattern on an image generated by the image generating device within a predetermined allowable range.

In one aspect, there is provided an arithmetic system for performing image matching process, comprising: a memory storing a model and a program, the model being constructed by machine learning; a processor configured to perform an arithmetic operation according to the program, the arithmetic system being configured to be operable to: convert a designated CAD pattern on design data into a CAD image; input the CAD image into the model; output a pseudo image from the model by performing calculations according to an algorithm defined by the model; and determine a pattern having a shape closest to a shape of a CAD pattern on the pseudo image, the determined pattern being one of patterns on an image generated by an image generating device.

In one aspect, the model comprises a model constructed by the machine learning using training data containing at least multiple CAD images converted from multiple CAD patterns on the design data and multiple images generated by the image generating device, the multiple images corresponding to the multiple CAD images.

In one aspect, the training data further contains training additional information data, and the training additional information data contains at least one of position information of the multiple CAD patterns, peripheral images converted from other CAD patterns existing around the multiple CAD patterns, and layer images converted from other CAD patterns existing above or below the multiple CAD patterns.

In one aspect, the arithmetic system is configured to input additional information data, in addition to the CAD image, into the model, and the additional information data contains at least one of position information of the designated CAD pattern, a peripheral image converted from a CAD pattern existing around the designated CAD pattern, and a layer image converted from a CAD pattern existing above or below the designated CAD pattern.

In one aspect, the arithmetic system is configured to perform machine learning to adjust parameters of the model such that a CAD pattern on a pseudo image output from the model matches a corresponding pattern on an image generated by the image generating device within a predetermined allowable range.

In one aspect, there is provided an arithmetic system for performing image matching process, comprising: a memory storing a model and a program, the model being constructed by machine learning; a processor configured to perform an arithmetic operation according to the program, the program being configured to cause the arithmetic system to perform the steps of: converting a designated CAD pattern on design data into a CAD image; inputting the CAD image into the model; outputting a pseudo image from the model by performing calculations according to an algorithm defined by the model; and determining a pattern having a shape closest to a shape of a CAD pattern on the pseudo image, the determined pattern being one of patterns on an image generated by an image generating device.

### Advantageous Effects of Invention

According to the present invention, the model constructed by the machine learning, such as deep learning, can accurately predict an actual pattern from a CAD pattern on design data. Specifically, the CAD pattern appearing on the pseudo image output from the model is expected to have a shape close to the actual pattern. Therefore, the arithmetic system can correctly align the CAD pattern on the pseudo image with the pattern on the image generated by the image generating device i.e., the arithmetic system can correctly perform the image matching process.

### BRIEF DESCRIPTION OF DRAWINGS

FIG. 1 is a schematic view showing an embodiment of an imaging apparatus;

FIG. 2 is a flowchart illustrating an embodiment in which a model is constructed by machine learning;

FIG. 3 is a schematic diagram showing an example of a CAD image converted from a CAD pattern;

FIG. 4 is a schematic view showing an example of a SEM image generated by a scanning electron microscope;

FIG. 5 is a schematic diagram showing an example of a model used in machine learning;

FIG. 6 is a flowchart illustrating an embodiment of a method of aligning a CAD pattern and a pattern on a SEM image (image matching process) using a model constructed by machine learning;

FIG. 7 is a schematic diagram showing examples of a CAD image, a SEM image, and a pseudo image;

FIG. 8 is a flowchart illustrating another embodiment in which a model is constructed by machine learning;

FIG. 9 is a flowchart illustrating another embodiment in which a model is constructed by machine learning;

FIG. 10 is a schematic view showing an example of a peripheral image;

FIG. 11 is a schematic diagram showing an example of layer images converted from CAD patterns of upper and lower layers that overlap with a designated CAD pattern;

FIG. 12 is a flowchart showing an embodiment of a method of aligning a CAD pattern and a pattern on a SEM image (image matching process) using a model created according to the flowchart shown in FIG. 9;

FIG. 13 is a schematic diagram showing an example of a matching process; and

FIG. 14 is a schematic diagram showing a CAD pattern and a corresponding pattern on an image.

### DESCRIPTION OF EMBODIMENTS

Hereinafter, embodiments of the present invention will be described with reference to the drawings.

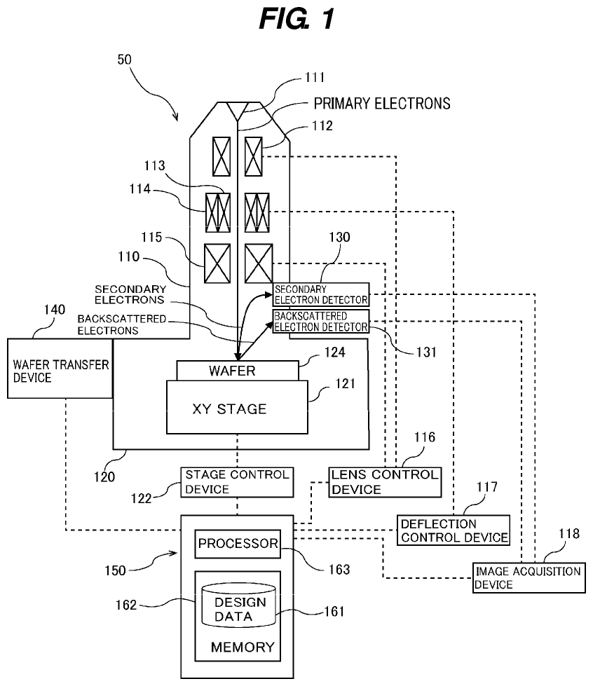

FIG. 1 is a schematic diagram showing an embodiment of an imaging apparatus. As shown in FIG. 1, the imaging apparatus includes a scanning electron microscope 50 and an arithmetic system 150. The scanning electron microscope 50 is an example of an image generating device. The scanning electron microscope 50 is coupled to the arithmetic system 150, and operations of the scanning electron microscope 50 are controlled by the arithmetic system 150.

The arithmetic system 150 includes a memory 162 in which a database 161 and programs are stored, and further includes a processor 163 configured to perform arithmetic operations according to the programs. The processor 163 includes a CPU (central processing unit) or a GPU (graphic processing unit) configured to perform the arithmetic operations according to the programs stored in the memory 162. The memory 162 includes a main memory (for example, a random-access memory) accessible by the processor 163 and an auxiliary memory (for example, a hard disk drive or a solid state drive) for storing data and programs.

The arithmetic system 150 includes at least one computer. For example, the arithmetic system 150 may be an edge server coupled to the scanning electron microscope 50 by a communication line, or may be a cloud server coupled to the scanning electron microscope 50 by a network, such as the Internet, or may be a fog computing device (e.g., gateway, fog server, router, etc.) installed in a network coupled to the scanning electron microscope 50. The arithmetic system 150 may be a combination of servers. For example, the arithmetic system 150 may be a combination of an edge server and a cloud server coupled to each other by a network, such as the Internet.

The scanning electron microscope 50 includes an electron gun 111 configured to emit an electron beam composed of primary electrons (charged particles), a converging lens 112 configured to converge the electron beam emitted by the electron gun 111, an X deflector 113 configured to deflect the electron beam in an X direction, a Y deflector 114 configured to deflect the electron beam in a Y direction, and an objective lens 115 configured to focus the electron beam on a wafer 124, which is a specimen.

The converging lens 112 and the objective lens 115 are coupled to a lens control device 116, so that operations of the converging lens 112 and the objective lens 115 are controlled by the lens control device 116. The lens control device 116 is coupled to the arithmetic system 150. The X deflector 113 and the Y deflector 114 are coupled to a deflection control device 117, so that the deflecting operations of the X deflector 113 and the Y deflector 114 are controlled by the deflection control device 117. The deflection control device 117 is also coupled to the arithmetic system 150. A secondary electron detector 130 and a backscattered electron detector 131 are coupled to an image acquisition device 118. The image acquisition device 118 is configured to convert output signals of the secondary electron detector 130 and the backscattered electron detector 131 into images. The image acquisition device 118 is also coupled to the arithmetic system 150.

A specimen stage 121, arranged in a specimen chamber 120, is coupled to a stage control device 122, so that the position of the specimen stage 121 is controlled by the stage control device 122. The stage control device 122 is coupled to the arithmetic system 150. A wafer transfer device 140 for placing the wafer 124 on the specimen stage 121 in the specimen chamber 120 is also coupled to the arithmetic system 150.

The electron beam emitted by the electron gun 111 is converged by the converging lens 112, and then focused by the objective lens 115 on the surface of the wafer 124, while the electron beam is deflected by the X deflector 113 and the Y deflector 114. When the wafer 124 is irradiated with the primary electrons of the electron beam, the secondary electrons and the backscattered electrons are emitted from the wafer 124. The secondary electrons are detected by the secondary electron detector 130, and the backscattered electrons are detected by the backscattered electron detector 131. Signals of the detected secondary electrons and signals of the detected backscattered electrons are input to the image acquisition device 118 and converted into images. The images are transmitted to the arithmetic system 150.

Design data for the wafer 124 is stored in advance in the memory 162. The design data for the wafer 124 includes pattern design information, such as coordinates of vertices of a pattern formed on the wafer 124, position, shape, and size of the pattern, and the number of a layer to which the pattern belongs. The database 161 is constructed in the memory 162. The design data for the wafer 124 is stored in advance in the database 161. The arithmetic system 150 can read out the design data for the wafer 124 from the database 161 stored in the memory 162.

Next, a matching process between a CAD pattern on the design data and a pattern on an image of the wafer generated by the scanning electron microscope 50 will be described. In the following descriptions, an actual image generated by the scanning electron microscope 50, which is the image generating device, may be referred to as a SEM image. The wafer pattern is formed based on the design data (also referred to as CAD data). CAD is an abbreviation for computer-aided design. The matching process is divided into a process of constructing a model by machine learning and a process of performing alignment (i.e., image matching process) between a CAD pattern on a pseudo image generated by using the model and a pattern on the SEM image.

The construction of the model and the image matching process are performed by the arithmetic system 150. The arithmetic system 150 includes at least one dedicated computer or general-purpose computer. When the arithmetic system 150 includes a plurality of computers including a first computer and a second computer, the first computer may perform the process of constructing the model, and the second computer may use the model to perform the alignment of the CAD pattern on the pseudo image with the pattern on the SEM image. The model created by the first computer may be temporarily stored in a semiconductor memory, such as a USB flash drive (also referred to as a USB memory), and then read from the semiconductor memory into the second computer. Alternatively, the model created by the first computer may be transmitted to the second computer through a communication network, such as the Internet or a local area network.

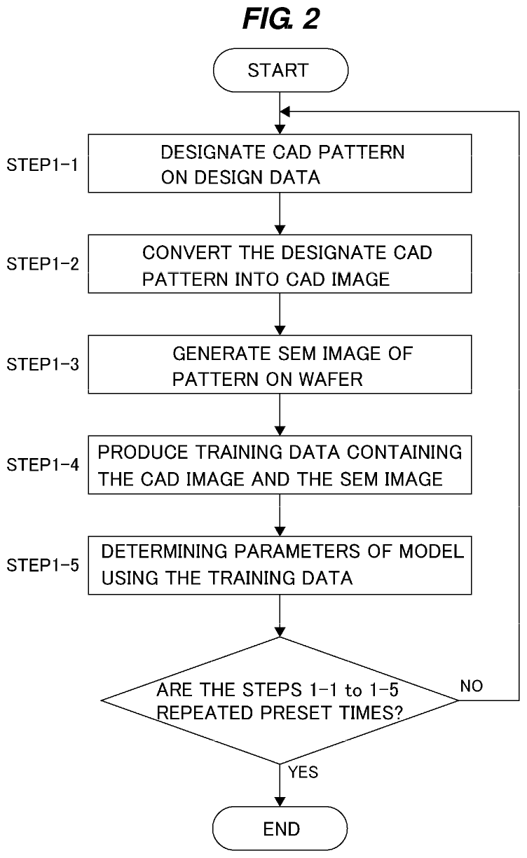

FIG. 2 is a flowchart illustrating an embodiment in which the model is constructed by the machine learning.

In step 1-1, the arithmetic system 150 designates a CAD pattern on the design data. The design data is data including design information of the pattern formed on the wafer. Specifically, the design data includes the coordinates of the vertices of the pattern, the position, shape, and size of the pattern, and the number of the layer to which the pattern belongs. The CAD pattern on the design data is a virtual pattern defined by the design information of the pattern included in the design data. This step 1-1 is a process of identifying a certain CAD pattern from multiple CAD patterns included in the design data. In this step 1-1, a plurality of CAD patterns may be designated.

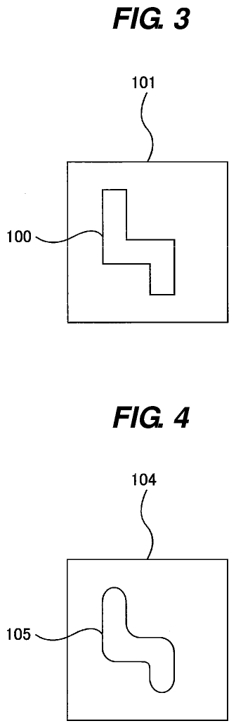

In step 1-2, the arithmetic system 150 converts the designated CAD pattern into a CAD image. More specifically, the arithmetic system 150 draws a CAD pattern 100 as shown in FIG. 3 based on the design information of the CAD pattern included in the design data (for example, the coordinates of the vertices of the CAD pattern) to thereby generate a CAD image 101 having a certain area. The arithmetic system 150 stores the generated CAD image 101 in the memory 162 of the arithmetic system 150.

In step 1-3, the scanning electron microscope 50 as an image generating device generates a SEM image of a pattern on the wafer that has been actually formed based on the CAD pattern designated in the step 1-1. FIG. 4 is a schematic view showing an example of the SEM image generated by the scanning electron microscope 50. In FIG. 4, a reference numeral 104 represents the SEM image, and a reference numeral 105 represents the pattern appearing on the SEM image 104. The pattern 105 corresponds to the above-designated CAD pattern, i.e., the CAD pattern 100 on the CAD image 101. The arithmetic system 150 acquires the SEM image 104 from the scanning electron microscope 50 and stores the SEM image 104 in the memory 162.

In step 1-4, the arithmetic system 150 produces training data containing the CAD image generated in the step 1-2 and the SEM image generated in the step 1-3.

In step 1-5, the arithmetic system 150 determines parameters (weighting factors, etc.) of the model by the machine learning using the training data containing the CAD image and the SEM image. In the machine learning, the CAD image contained in the training data is used as an explanatory variable, and the SEM image contained in the training data is used as an objective variable.

The arithmetic system 150 and the scanning electron microscope 50 repeat the above-mentioned steps 1-1 to 1-5 a preset number of times to construct the model according to the machine learning. Specifically, the model is constructed by the machine learning using the training data containing multiple CAD images converted from multiple CAD patterns on the design data and multiple SEM images corresponding to these CAD images. The model constructed by the machine learning in this way may be referred to as a trained model. The arithmetic system 150 stores the model in the memory 162. While the steps 1-1 to 1-5 are repeated, the same design data may be used, or a plurality of design data may be used.

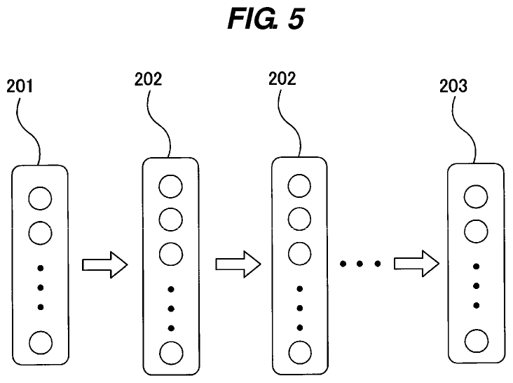

FIG. 5 is a schematic diagram showing an example of the model used in the machine learning. This model is a neural network having an input layer 201, a plurality of intermediate layers (also referred to as hidden layers) 202, and an output layer 203. A CAD image is input to the input layer 201 of the model. More specifically, numerical values of respective pixels constituting the CAD image are input to the input layer 201. In one example, in a case where the CAD image is a grayscale image, a numerical value indicating a gray level of each pixel is input to each node (or neuron) of the input layer 201 of the model. The output layer 203 outputs numerical values of pixels corresponding to the pixels constituting the CAD image that has been input to the input layer 201.

Deep learning may be suitable as an algorithm of the machine learning. Deep learning is a learning method based on a neural network having multiple intermediate layers. In this specification, machine learning using a neural network having an input layer, a plurality of intermediate layers (hidden layers), and an output layer is referred to as deep learning. The model constructed by the deep learning can accurately predict the shape of pattern that can be deformed due to various factors.

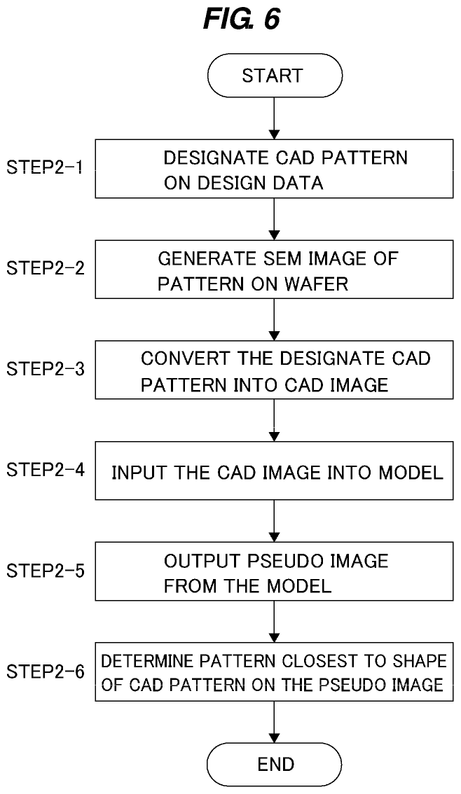

Next, an embodiment of a method of aligning a CAD pattern and a pattern on a SEM image (i.e., image matching process) using the above-discussed model composed of a neural network that has been constructed by the machine learning will be described with reference to a flowchart shown in FIG. 6.

In step 2-1 the arithmetic system 150 designates a CAD pattern on the design data.

In step 2-2, the scanning electron microscope 50 generates a SEM image (i.e., an actual image) of patterns actually formed on the wafer based on the design data used in the step 2-1. The arithmetic system 150 acquires the SEM image from the scanning electron microscope 50 and stores the SEM image in the memory 162.

In step 2-3, the arithmetic system 150 converts the CAD pattern designated in the step 2-1 into a CAD image. The arithmetic system 150 stores the CAD image in the memory 162.

In step 2-4, the arithmetic system 150 inputs the CAD image obtained in the step 2-3 into the above-discussed model.

In step 2-5, the arithmetic system 150 outputs a pseudo image from the model by performing calculations according to algorithm defined by the model.

In step 2-6, the arithmetic system 150 determines a pattern having a shape closest to a shape of a CAD pattern on the pseudo image from the patterns on the SEM image generated in the step 2-2. A known technique, such as a phase-only correlation method, can be used to determine the similarity between a pattern on the SEM image and the CAD pattern on the pseudo image.

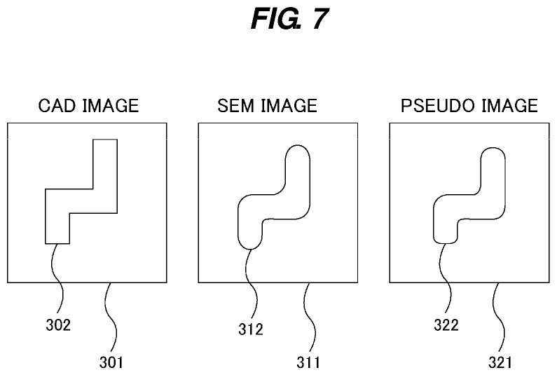

FIG. 7 is a schematic view showing examples of the CAD image, the SEM image, and the pseudo image. Since the CAD pattern 302 on the CAD image 301 is created based on the coordinates of each vertex of the CAD pattern included in the design data, the CAD pattern 302 is composed of linear line segments. In contrast, an actual pattern 312 on a SEM image 311 is deformed as compared with the CAD pattern 302 due to the manufacturing process and/or the imaging process. A CAD pattern 322 on a pseudo image 321 output from the model has a shape close to the actual pattern 312 on the SEM image 311.

According to this embodiment, the model constructed by the machine learning, such as deep learning, can accurately predict the actual pattern from the CAD pattern on the design data. Specifically, the CAD pattern appearing on the pseudo image output from the model is expected to have a shape close to the actual pattern. Therefore, the arithmetic system 150 can correctly align the CAD pattern on the pseudo image with the pattern on the image generated by the image generating device (i.e., the arithmetic system 150 can correctly perform the image matching process).

The arithmetic system 150 and the scanning electron microscope 50 perform the above-discussed steps 2-1 to 2-6 according to instructions included in the program stored in the memory 162. The program may be first stored in a non-transitory tangible computer-readable storage medium, and then provided to the arithmetic system 150 via the storage medium. Alternatively, the program may be provided to the computing system 150 via a communication network, such as the Internet or a local area network.

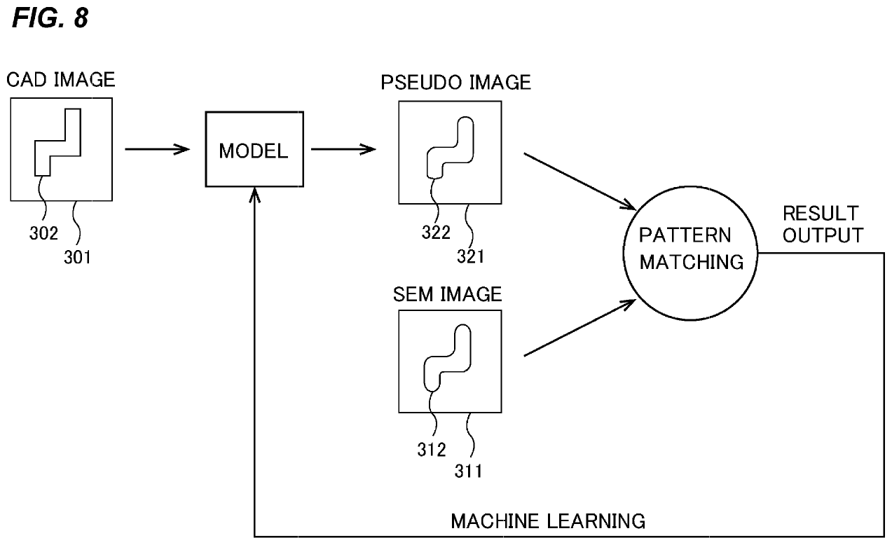

In one embodiment, in order to enable the model to output a pseudo image more suitable for the pattern matching, the arithmetic system 150 may adjust the model parameters (such as weighting factors) using the result of the pattern matching between the CAD pattern on the pseudo image and the pattern on the SEM image. Hereinafter, this embodiment will be described with reference to FIG. 8.

The arithmetic system 150 inputs the CAD image 301 converted from the CAD pattern on the design data into the model. Next, the arithmetic system 150 performs the pattern matching between the CAD pattern 322 on the pseudo image 321 output from the model and the pattern 312 on the SEM image (actual image) 311 contained in the training data that has been used for constructing the model. The SEM image 311 used for this pattern matching corresponds to the CAD image 301 input to the model. The pattern matching is performed according to a known algorithm for determining whether the CAD pattern 322 on the pseudo image 321 matches the pattern 312 on the SEM image 311.

The arithmetic system 150 outputs the result of pattern matching. Specifically, if the CAD pattern 322 on the pseudo image 321 output from the model matches the pattern 312 on the SEM image 311 within a predetermined allowable range, the arithmetic system 150 outputs a first numerical value (for example, 1) indicating that the pattern matching was successful. On the other hand, if the CAD pattern 322 on the pseudo image 321 output from the model does not match the pattern 312 on the SEM image 311 within the predetermined allowable range, the arithmetic system 150 outputs a second numerical value (for example, 0) indicating that the pattern matching has failed.

If the arithmetic system 150 outputs the second numerical value, the arithmetic system 150 performs the machine learning to adjust the parameters of the model such that the first numerical value is output as a result of the pattern matching, and then performs the pattern matching. Specifically, the arithmetic system 150 performs the machine learning to adjust the parameters of the model such that the CAD pattern 322 on the pseudo image 321 output from the model matches the pattern 312 on the SEM image 311 within the predetermined allowable range. Such operation enables the model to output the pseudo image 321 more suitable for the pattern matching.

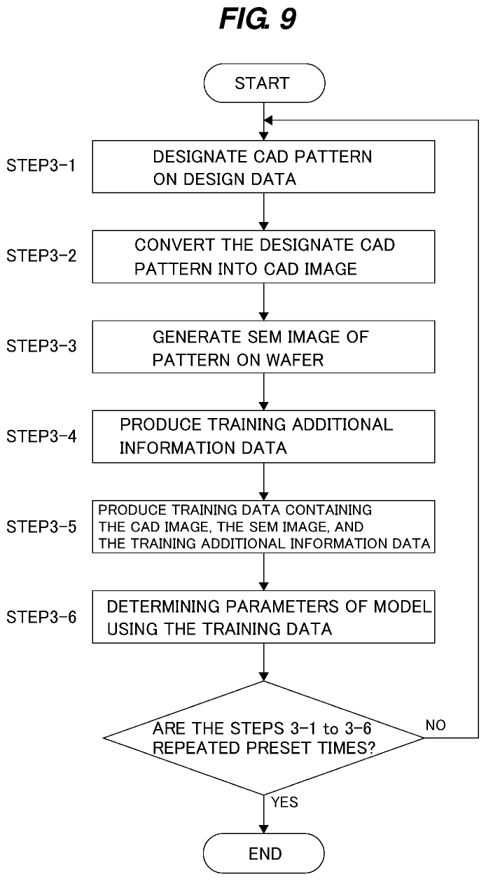

FIG. 9 is a flowchart illustrating another embodiment for constructing a model composed of a neural network by machine learning. Since steps 3-1 to 3-3 of this embodiment are the same as the steps 1-1 to 1-3 shown in FIG. 2, the repetitive descriptions thereof will be omitted.

In the present embodiment, the training data used for constructing the model further contains training additional information data in order to make the shape of the CAD pattern on the pseudo image closer to the shape of the actual pattern on the wafer.

Specifically, in step 3-4, the arithmetic system 150 produces training additional information data including at least one of position information of the CAD pattern designated in the step 3-1, a peripheral image converted from CAD patterns existing around the CAD pattern designated in the step 3-1, and a layer image converted from a CAD pattern existing above or below the CAD pattern designated in the step 3-1. In one embodiment, the layer image may be layer images converted from CAD patterns existing above and below the designated CAD pattern.

The position information of the CAD pattern is contained in the design data. Therefore, the arithmetic system 150 can obtain the position information of the designated CAD pattern from the design data. The peripheral image is generated by the arithmetic system 150. More specifically, the arithmetic system 150 draws these CAD patterns based on the design information of the CAD patterns existing around the designated CAD pattern to generate the peripheral image having a certain area.

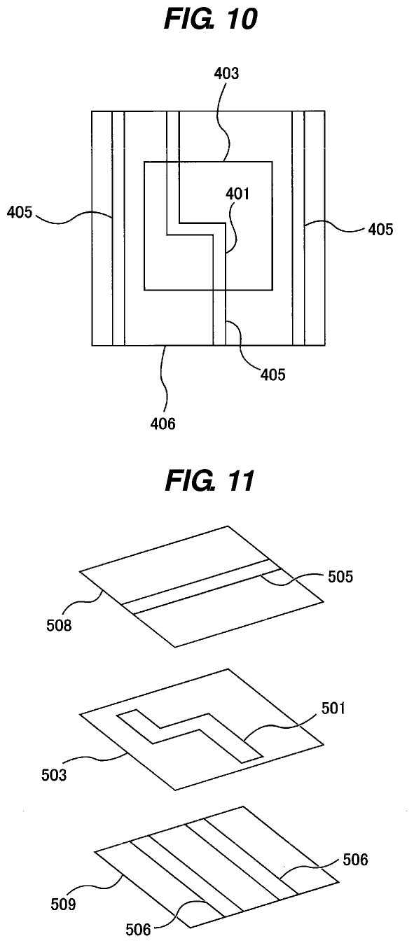

FIG. 10 is a schematic view showing an example of the peripheral image. In FIG. 10, a reference numeral 401 represents the CAD pattern designated in the step 3-1, a reference numeral 403 represents the CAD image generated in the step 3-2, and reference numerals 405 represent CAD patterns existing around the CAD image 403, and a reference numeral 406 represents the peripheral image converted from the CAD patterns 405.

The layer image is also generated by the arithmetic system 150. More specifically, the arithmetic system 150 draws CAD patterns, existing above and/or below the designated CAD pattern, based on the design information of these CAD patterns, and generates the layer image having a certain area.

FIG. 11 is a schematic diagram showing an example of layer images converted from CAD patterns existing above and below the designated CAD pattern. In FIG. 11, a reference numeral 501 represents the CAD pattern designated in the step 3-1, a reference numeral 503 represents the CAD image generated in the step 3-2, and reference numerals 505 and 506 represent CAD patterns existing in upper and lower layers overlapping the designated CAD pattern, and reference numerals 508 and 509 represent layer images converted from the CAD patterns 505 and 506 of the upper and lower layers.

Referring back to FIG. 9, in step 3-5, the arithmetic system 150 produces the training data containing the CAD image generated in the step 3-2, the SEM image generated in the step 3-3, and the training additional information data created in the step 3-4.

In step 3-6, the arithmetic system 150 performs the machine learning using the above-discussed training data to determine the parameters (weighting factors, etc.) of the model constituted by the neural network. The structure of the model used in this embodiment is basically the same as that of the model shown in FIG. 5, but is different in that the input layer of the model according to this embodiment further includes nodes (neurons) into which the training additional information data is input.

The arithmetic system 150 and the scanning electron microscope 50 repeat the above-discussed steps 3-1 to 3-6 the preset number of times to construct the model according to the machine learning. Specifically, the model is constructed by the machine learning using the training data that contains: multiple CAD images converted from multiple CAD patterns on the design data; multiple SEM images corresponding to these CAD images; and the training additional information data. The training additional information data contains at least one of position information of the multiple CAD patterns obtained by repeating the step 3-1, multiple peripheral images converted from other CAD patterns existing around the multiple CAD patterns, and multiple layer images converted from other CAD patterns existing above or below the multiple CAD patterns. In one embodiment, the multiple layer images may be multiple layer images converted from other CAD patterns existing above and below the multiple CAD patterns.

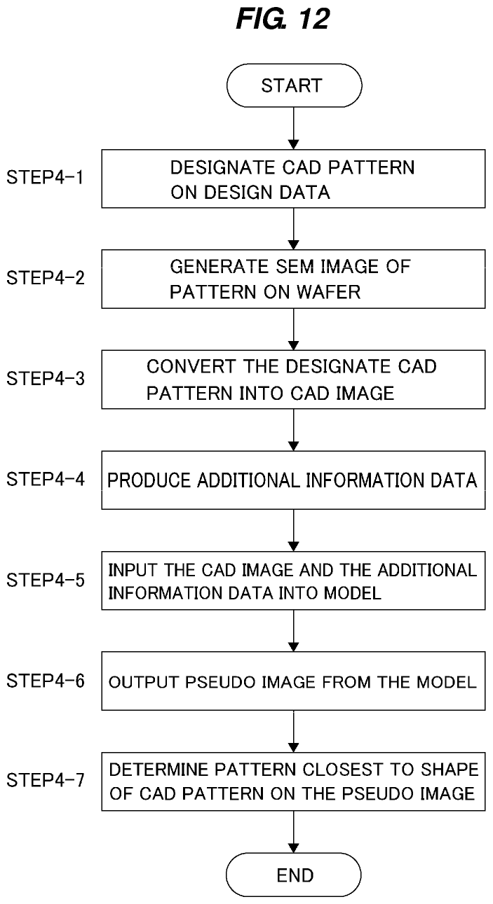

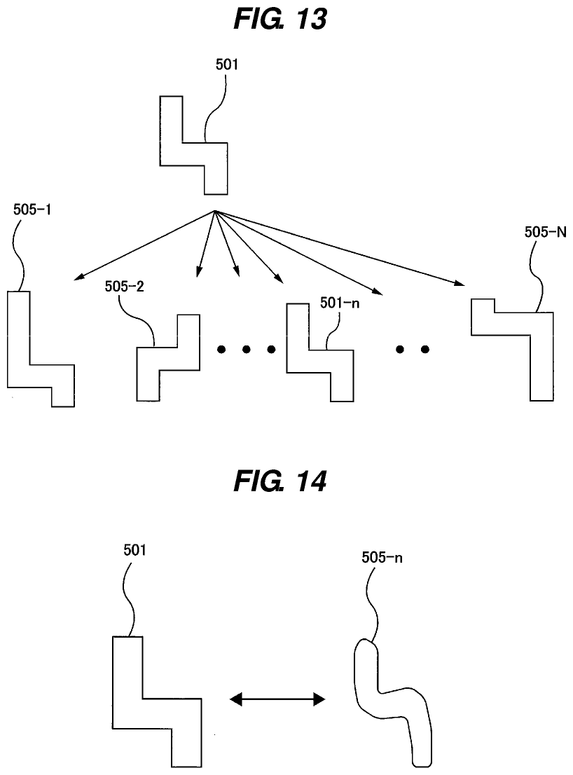

FIG. 12 is a flowchart showing an embodiment of a method of aligning a CAD pattern and a pattern on a SEM image (i.e., image matching process) using the model created according to the flowchart shown in FIG. 9.

In step 4-1, the arithmetic system 150 designates a CAD pattern on the design data.

In step 4-2, the scanning electron microscope 50 generates a SEM image (an actual image) of patterns that have been actually formed on the wafer based on the design data used in the step 4-1. The arithmetic system 150 acquires the SEM image from the scanning electron microscope 50 and stores the SEM image in the memory 162.

In step 4-3, the arithmetic system 150 converts the CAD pattern designated in the step 4-1 into a CAD image. The arithmetic system 150 stores the CAD image in the memory 162.

In step 4-4, the arithmetic system 150 creates additional information data related to the CAD pattern designated in the step 4-1. This additional information data contains at least one of: position information of the CAD pattern designated in the step 4-1; a peripheral image converted from CAD patterns existing around the designated CAD pattern; and a layer image converted from CAD pattern existing above or below the designated CAD pattern. In one embodiment, the layer image may be layer images converted from CAD patterns existing above and below the designated CAD pattern.

The position information of the CAD pattern is contained in the design data. Therefore, the arithmetic system 150 can obtain the position information of the designated CAD pattern from the design data. The peripheral image is generated by the arithmetic system 150. More specifically, the arithmetic system 150 draws CAD patterns existing around the designated CAD pattern based on the design information of these CAD patterns (for example, the coordinates of the vertices of these CAD patterns) to generate the peripheral image having a certain area. The layer image is also generated by the arithmetic system 150. More specifically, the arithmetic system 150 draws CAD patterns existing above and/or below the designated CAD pattern based on the design information of these CAD patterns (for example, the coordinates of the vertices of these CAD patterns) to generate the layer image(s) having a certain area.

The above descriptions of the peripheral image and the layer image contained in the training additional information data, and FIGS. 10 and 11 can be applied to the peripheral image and the layer image contained in the additional information data, and thus depictions thereof are omitted.

In step 4-5, the arithmetic system 150 inputs the CAD image obtained in the step 4-3 and the additional information data produced in the step 4-4 into the model.

In step 4-6, the arithmetic system 150 outputs a pseudo image from the model by executing the calculations according to the algorithm defined by the model.

In step 4-7, the arithmetic system 150 determines, among the patterns on the SEM image generated in the step 4-2, a pattern having a shape closest to the shape of the CAD pattern on the pseudo image.

A deformation tendency of a pattern appearing on a SEM image can vary depending on factors, such as the position of the pattern, other patterns existing around the pattern, and other patterns existing above and/or below the pattern. Specifically, these factors can affect the shape of the pattern on the SEM image. According to the above-discussed embodiments, the model is constructed using the training additional information data, and the additional information data is input to the model. Therefore, the model can predict a pattern having a shape closer to the CAD pattern. Therefore, the arithmetic system 150 can more correctly align the CAD pattern on the pseudo image with the pattern on the image generated by the scanning electron microscope 50 (i.e., the arithmetic system 150 can more correctly perform the image matching process).

The embodiment described with reference to FIG. 8 can also be applied to the embodiments shown in FIGS. 9 to 12.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention relates to an image matching process for aligning a pattern on design data with a pattern on an image, and is applicable to an image matching process using a model constructed by machine learning.

### Reference Signs List

100 scanning electron microscope

111 electron gun

112 converging lens

113 X deflector

114 Y deflector

115 objective lens

116 lens control device

117 deflection control device

118 image acquisition device

120 specimen chamber

121 specimen stage

122 stage control device

124 wafer

130 secondary electron detector

131 backscattered electron detector

140 wafer transfer device

150 arithmetic system

161 database

162 memory

163 processor

1. A method comprising:
converting a designated CAD pattern on design data into a CAD image;
inputting the CAD image into a model constructed by machine learning;
outputting a pseudo image from the model by performing calculations according to an algorithm defined by the model;
determining a pattern having a shape closest to a shape of a CAD pattern on the pseudo image, the determined pattern being one of patterns on an image generated by an image generating device; and
performing machine learning to adjust parameters of the model such that a CAD pattern on a pseudo image output from the model matches a corresponding pattern on an image generated by the image generating device within a predetermined allowable range.

2. A method comprising:
converting a designated CAD pattern on design data into a CAD image;
inputting the CAD image into a model constructed by machine learning;
outputting a pseudo image from the model by performing calculations according to an algorithm defined by the model; and
determining a pattern having a shape closest to a shape of a CAD pattern on the pseudo image, the determined pattern being one of patterns on an image generated by an image generating device,
wherein the model comprises a model constructed by the machine learning using training data containing at least multiple CAD images converted from multiple CAD patterns on the design data and multiple images generated by the image generating device, the multiple images corresponding to the multiple CAD images, and
the training data further contains training additional information data, the training additional information data containing at least one of position information of the multiple CAD patterns, peripheral images converted from other CAD patterns existing around the multiple CAD patterns, and layer images converted from other CAD patterns existing above or below the CAD patterns.

3. (canceled)

4. The method according to claim 2, wherein:
inputting the CAD image into the model comprises inputting the CAD image and additional information data into the model; and
the additional information data contains at least one of position information of the designated CAD pattern, a peripheral image converted from a CAD pattern existing around the designated CAD pattern, and a layer image converted from a CAD pattern existing above or below the designated CAD pattern.

5. (canceled)

6. An arithmetic system for performing image matching process, comprising:
a memory storing a model and a program, the model being constructed by machine learning;
a processor configured to perform an arithmetic operation according to the program, the arithmetic system being configured to be operable to:
convert a designated CAD pattern on design data into a CAD image;
input the CAD image into the model;
output a pseudo image from the model by performing calculations according to an algorithm defined by the model;
determine a pattern having a shape closest to a shape of a CAD pattern on the pseudo image, the determined pattern being one of patterns on an image generated by an image generating device; and
perform machine learning to adjust parameters of the model such that a CAD pattern on a pseudo image output from the model matches a corresponding pattern on an image generated by the image generating device within a predetermined allowable range.

7. An arithmetic system for performing image matching process, comprising:
a memory storing a model and a program, the model being constructed by machine learning;
a processor configured to perform an arithmetic operation according to the program, the arithmetic system being configured to be operable to:
convert a designated CAD pattern on design data into a CAD image;
input the CAD image into the model;
output a pseudo image from the model by performing calculations according to an algorithm defined by the model; and
determine a pattern having a shape closest to a shape of a CAD pattern on the pseudo image, the determined pattern being one of patterns on an image generated by an image generating device,
wherein the model comprises a model constructed by the machine learning using training data containing at least multiple CAD images converted from multiple CAD patterns on the design data and multiple images generated by the image generating device, the multiple images corresponding to the multiple CAD images, and
the training data further contains training additional information data, the training additional information data containing at least one of position information of the multiple CAD patterns, peripheral images converted from other CAD patterns existing around the multiple CAD patterns, and layer images converted from other CAD patterns existing above or below the multiple CAD patterns.

8. (canceled)

9. The arithmetic system according to claim 7, wherein:
the arithmetic system is configured to input additional information data, in addition to the CAD image, into the model; and
the additional information data contains at least one of position information of the designated CAD pattern, a peripheral image converted from a CAD pattern existing around the designated CAD pattern, and a layer image converted from a CAD pattern existing above or below the designated CAD pattern.

10. (canceled)
